(19) United States
(12) Patent Application Publication
(10) Pub. No.: US 2017/0306474 A1
(43) Pub. Date: Oct. 26, 2017

(54) INTEGRATION OF LASER PROCESSING WITH DEPOSITION OF ELECTROCHEMICAL DEVICE LAYERS

(71) Applicant: APPLIED MATERIALS, INC., Santa Clara, CA (US)

(72) Inventors: Byung-Sung Leo KWAK, Portland, OR (US); Stephen MOFFATT, St. Brelade (JE)

(21) Appl. No.: 15/517,910

(22) PCT Filed: Nov. 2, 2015
(86) PCT No.: PCT/US2015/058638

§ 371 Date: Apr. 7, 2017

Related U.S. Application Data
(60) Provisional application No. 62/073,818, filed on Oct. 31, 2014.

(51) Int. Cl. C23C 14/56; C23C 14/58; H01M 10/0562; H01M 10/0585; C23C 14/08; C23C 14/04; H01M 10/04; H01M 4/485

(52) U.S. Cl. CPC C23C 14/568; H01M 10/0436; C23C 14/5813; H01M 4/485; H01M 10/0585; C23C 14/08; C23C 14/048; H01M 10/0562

(57) ABSTRACT

A method of fabricating an electrochemical device in an apparatus may comprise: providing an electrochemical device substrate; depositing a device layer over the substrate; applying electromagnetic radiation to the device layer in situ to effect one or more of surface restructuring, recrystallization and densification of the device layer; repeating the depositing and the applying until a desired device layer thickness is achieved. Furthermore, the applying may be during the depositing. A thin film battery may comprise: a substrate; a current collector on the substrate; a cathode layer on the current collector; an electrolyte layer on the cathode layer; and a lithium anode layer on the electrolyte layer; wherein the LLZO electrolyte layer has a crystalline phase, no shorts due to cracks in the LLZO electrolyte layer, and no highly resistive interlayer at the interface between the electrolyte layer and the cathode layer.

### CROSS-REFERENCE TO RELATED APPLICATIONS

This application claims the benefit of U.S. Provisional Application No. 62/073,818 filed Oct. 31, 2014, incorporated by reference herein in its entirety.

### FIELD

Embodiments of the present disclosure relate generally to tools and methods for fabrication of electrochemical devices, and more specifically, but not exclusively, integration of laser processing with deposition of electrochemical device layers.

### BACKGROUND

Electrochemical devices, such as a solid state thin film battery (TFB), comprise a stack of many layers including current collectors, cathode (positive electrode), solid state electrolyte and anode (negative electrode). A challenge in fabricating these devices is forming layers of material with the crystallinity, crystal phase, surface morphology, material density and pinhole density needed for satisfactory performance of the completed devices, when considering the type of the materials used in these devices—ceramics, dielectrics, metal oxides, phosphorus oxynitrides, etc. These materials have low surface mobility and high activation energy to form material with the desired characteristics. The device performance, yield, manufacturability and cost will depend on how well and easily the layers with satisfactory crystallinity, phase and density can be created. There is clearly a needed for tools and methods for fabrication of device layers with the desired material characteristics.

### SUMMARY

The present disclosure describes deposition and processing tools and methods for improving the characteristics of the layers of electrochemical devices, the latter including energy storage devices such as thin film batteries (TFBs), electrochromic devices, etc. The layer characteristics of interest include crystallinity, surface morphology, material density, and pinhole density. The hardware and methods include the integration of laser processing of device layers with layer deposition, wherein the processing is in situ, and are agnostic to both the material types and deposition methods (PVD, CVD, ALD, etc.).

According to some embodiments, a method of fabricating an electrochemical device in an apparatus may comprise: providing an electrochemical device substrate; depositing a device layer over the substrate; applying electromagnetic radiation to the device layer in situ to effect one or more of surface restructuring, recrystallization and densification of the device layer; repeating the depositing and the applying until a desired device layer thickness is achieved.

According to some embodiments, an apparatus for manufacturing electrochemical devices may comprise: a first system for depositing a device layer over the substrate; a second system for applying electromagnetic radiation to the device layer to effect one or more of surface restructuring, recrystallization and densification of the device layer; a third system for repeating the depositing and a fourth system for repeating the applying.

According to some embodiments, a thin film battery may comprise: a substrate; a current collector on the substrate; a cathode layer on the current collector; an electrolyte layer on the cathode layer; and a lithium anode layer on the electrolyte layer; wherein the LLZO electrolyte layer has a crystalline phase, no shorts due to cracks in the LLZO electrolyte layer, and no highly resistive interlayer at the interface between the electrolyte layer and the cathode layer.

### BRIEF DESCRIPTION OF THE DRAWINGS

These and other aspects and features of the present disclosure will become apparent to those ordinarily skilled in the art upon review of the following description of specific embodiments in conjunction with the accompanying figures, wherein:

FIG. 1 is a cross-sectional representation of a first example of a TFB device, according to some embodiments;

FIG. 2 is a cross-sectional representation of a second example of a TFB device, according to some embodiments;

FIG. 3 is a top-down plan view schematic representation of an in-line processing system, according to some embodiments;

FIG. 4 is a first process flow for laser assisted deposition of an electrochemical device layer, according to some embodiments;

FIG. 5 is a second process flow for laser assisted deposition of an electrochemical device layer, according to some embodiments;

FIG. 6 is a schematic representation of an example of a sputter deposition tool that could be used in the in-line processing system of FIG. 3, according to some embodiments;

FIG. 7 is a schematic representation of an example of a first laser processing tool that could be used in the in-line processing system of FIG. 3, according to some embodiments;

FIG. 8 is a schematic representation of an example of a second laser processing tool that could be used in the in-line processing system of FIG. 3, according to some embodiments; and

FIG. 9 is a schematic representation of an example of a third laser processing tool that could be used in the in-line processing system of FIG. 3, according to some embodiments.

### DETAILED DESCRIPTION

Embodiments of the present disclosure will now be described in detail with reference to the drawings, which are provided as illustrative examples of the disclosure so as to enable those skilled in the art to practice the disclosure. The drawings provided herein include representations of devices and device process flows which are not drawn to scale. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. In the present disclosure, an embodiment showing a singular component should not be considered limiting; rather, the disclosure is intended to encompass other embodiments including a plurality of the same component, and vice-versa, unless explicitly stated otherwise herein. Moreover, it is not intended for any term in the present disclosure to be ascribed an uncommon or special meaning unless explicitly set forth as such. Further, the present disclosure encompasses present and future known equivalents to the known components referred to herein by way of illustration.

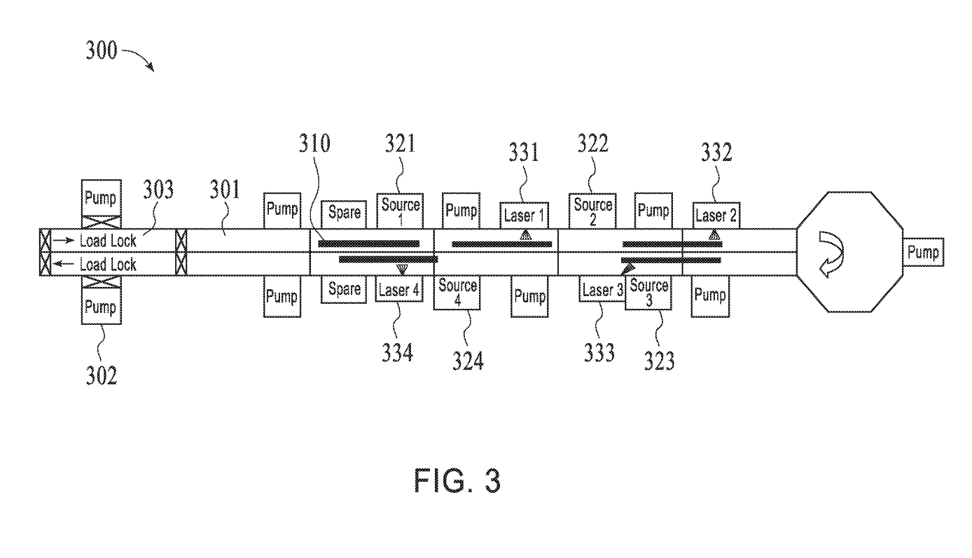

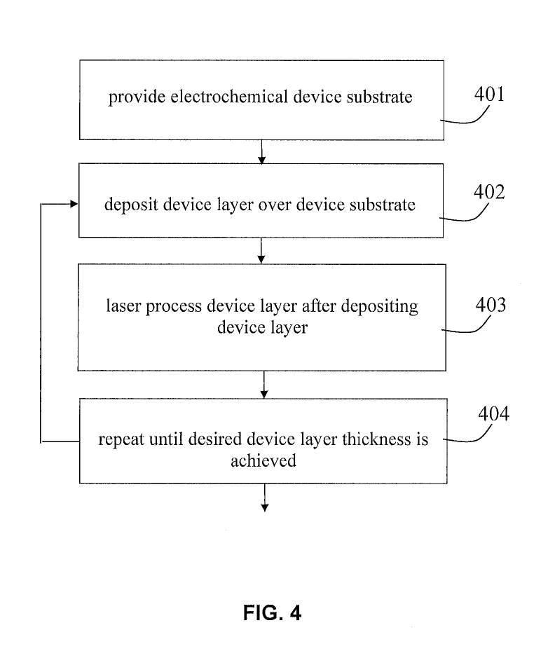

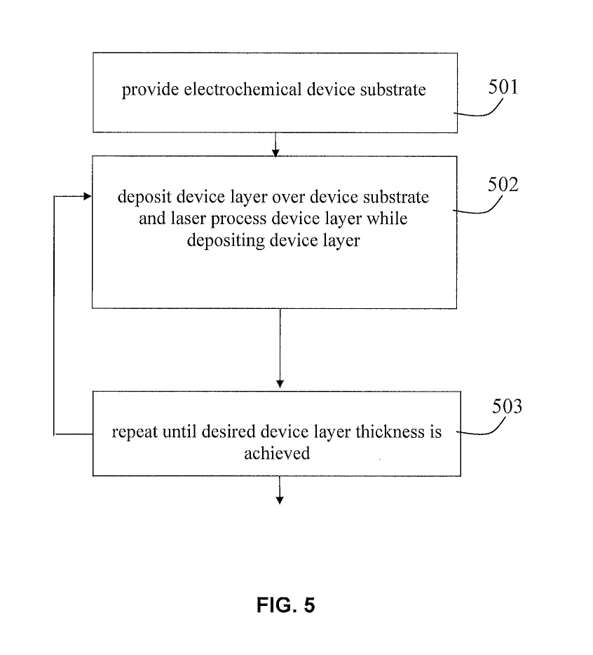

The present disclosure describes deposition and processing tools and methods for improving the characteristics of the layers of electrochemical devices, the latter including energy storage devices such as thin film batteries (TFBs), electrochromic devices, etc. The layer characteristics of interest include crystallinity, surface morphology, material density, and pinhole density. The hardware and methods are agnostic to both the material types and deposition methods (PVD, CVD, ALD, etc.). The method for improving device layer material characteristics includes imparting energy to the deposition system to overcome the energetics associated with surface mobility and crystallization—it is proposed herein to integrate laser processing into the processing hardware and fabrication methods. Furthermore, it may also be possible to minimize the thermal budget to the overall device by limiting the heating during deposition to only the desired layer and thereby limiting wide spreading of the heat—a challenge that can also be met by integrating laser processing into the processing hardware and fabrication methods. A schematic representation of a linear deposition system into which laser processing is integrated is shown in FIG. 3, and process flows are shown in FIGS. 4-5, described in more detail below.

In situ improvement of the crystallinity and phase of the cathode materials may lead to simplified process integration and improved device performance, for example, with a lower thermal budget during post-deposition anneal, leading to lower stack stress and thus to better yield and longer term device robustness. Better surface morphology (of the cathode) and zero pinhole density (of the electrolyte) may lead to better device yield and to per-unit manufacturing cost reduction. If the electrolyte deposition can achieve zero pinhole density at a lower layer thickness, this may lead to a significant manufacturing cost reduction due to the lesser requirement for deposited film thickness for a given production capacity. Furthermore, such reduction in electrolyte thickness may also lead to device performance improvements through lower internal impedance of the device. Improvement in the material density of the cathode layer (which equates to energy content of the device) may lead to a higher energy content for a given layer thickness. Such improvements in the mass density and energy density may be utilized in creating devices with high volumetric and gravimetric energy density.

FIG. 1 shows a representation of a first TFB device structure 100 with cathode current collector 102 and anode current collector 103 formed on a substrate 101, followed by cathode 104, electrolyte 105 and anode 106, wherein one or more of the device layers is formed using the integrated laser processing and deposition according to embodiments of the present disclosure; although the device may be fabricated with the cathode, electrolyte and anode in reverse order. Note a layer is shown on top of the substrate 101, which is an optional insulating layer used to electrically isolate the anode and cathode current collectors when an electrically conductive substrate (such as a metal) is used. Furthermore, the cathode current collector (CCC) and anode current collector (ACC) may be deposited separately. For example, the CCC may be deposited before the cathode and the ACC may be deposited after the electrolyte. The device may be covered by an encapsulation layer 107 to protect the environmentally sensitive layers from oxidizing agents. Note that the component layers are not necessarily drawn to scale in the TFB device shown in FIG. 1. The structure of FIG. 1 is typical of a device formed using shadow masks.

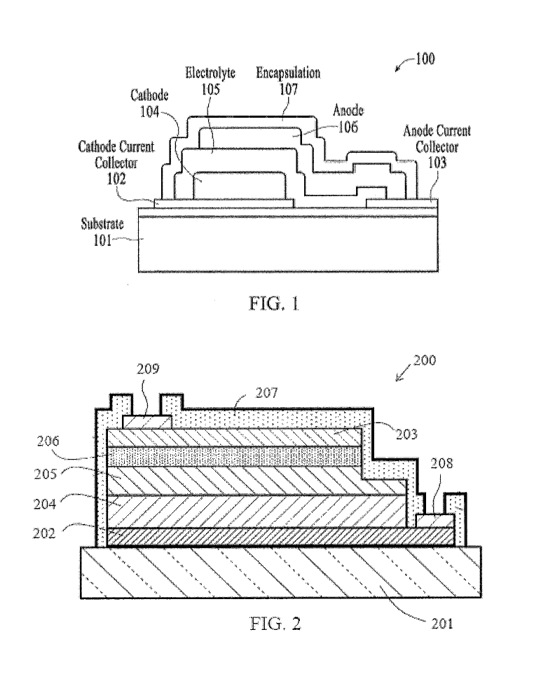

FIG. 2 shows a representation of a second example TFB device structure 200 comprising a substrate 201 (e.g. glass), a current collector layer 202 (e.g. Ti/Au), a cathode layer 204 (e.g. LiCoO₂), an electrolyte layer 205 (e.g. LiPON), an anode layer 206 (e.g. Li, Si), an ACC layer 203 (e.g. Ti/Au), bonding pads (Al, for example) 208 and 209 for ACC and CCC, respectively, and a blanket encapsulation layer 207 (polymer, silicon nitride, for example), wherein one or more of the device layers is formed using the integrated laser processing and deposition according to embodiments of the present disclosure. Note that the component layers are not necessarily drawn to scale in the TFB device shown in FIG. 2. The structure of FIG. 2 is typical of a device formed using direct patterning of layers—using laser ablation, for example.

The specific TFB device structures provided above with reference to FIGS. 1 & 2 are merely examples and it is expected that embodiments of the present disclosure may be applicable to a wide variety of different TFB structures.

Furthermore, a wide range of materials may be utilized for the different TFB device layers. For example, a substrate may be a glass substrate, a cathode layer may be a LiCoO₂ layer (deposited by e.g. RF sputtering, pulsed DC sputtering, etc.), an anode layer may be a Li metal layer (deposited by e.g. evaporation, sputtering, etc.), and an electrolyte layer may be a LiPON layer (deposited by e.g. RF sputtering, etc.). However, it is expected that the present disclosure may be applied to a wider range of TFBs comprising different materials. Furthermore, deposition techniques, with which laser processing is integrated according to embodiments, for these layers may include deposition techniques such as PVD, PECVD, reactive sputtering, non-reactive sputtering, RF sputtering, multi-frequency sputtering, electron and ion beam evaporation, thermal evaporation, CVD, ALD, etc.; the deposition method can also be non-vacuum based, such as plasma spray, spray pyrolysis, slot die coating, screen printing, etc. For a PVD sputter deposition process, the process may be AC, DC, pulsed DC, RF, HF (e.g., microwave), etc., or combinations thereof.

Examples of materials for the different component layers of a TFB may include one or more of the following. The substrate may be silicon, silicon nitride on Si, glass, PET (polyethylene terephthalate), mica, metal foils such as copper, etc. The ACC and CCC may be one or more of Ag, Al, Au, Ca, Cu, Co, Sn, Pd, Zn and Pt which may be alloyed and/or present in multiple layers of different materials and/or include an adhesion layer of a one or more of Ti, Ni, Co, refractory metals and super alloys, etc. The cathode may be LiCoO₂, V₂O₅, LiMnO₂, Li₅FeO₄, NMC (NiMnCo oxide), NCA (NiCoAl oxide), LMO (LiₓMnO₂), LFP (LiₓFePO₄), LiMn spinel, etc. The solid electrolyte may be a lithium-conducting electrolyte material including materials such as LiPON, LiI/A1₂O₃ mixtures, LLZO (LiLaZr oxide), LiSiCON, Ta₂O₅, etc. The anode may be Li, Si, silicon-lithium alloys, lithium silicon sulfide, Al, Sn, C, etc. and other lower-potential Li salts, such as Li₄Ti₅O₁₂.

The anode/negative electrode layer may be pure lithium metal or may be a Li alloy, where the Li is alloyed with a metal such as tin or a semiconductor such as silicon, for example. The Li layer may be about 3 μm thick (as appropriate for the cathode and capacity balancing) and the encapsulation layer may be 3 μm or thicker. The encapsulation layer may be a multilayer of polymer/parylene and metal and/or dielectric. Note that, between the formation of the Li layer and the encapsulation layer, the part should be kept in an inert or very low humidity environment, such as argon gas or in a dry-room; however, after blanket encapsulation layer deposition the requirement for an inert environment will be relaxed. The ACC may be used to protect the Li layer allowing laser ablation outside of vacuum and the requirement for an inert environment may be relaxed.

Furthermore, the metal current collectors, both on the cathode and anode side, may need to function as protective barriers to the shuttling lithium ions. In addition, the anode current collector may need to function as a barrier to oxidants (e.g. H₂O, O₂, N₂, etc.) from the ambient. Therefore, the current collector metals may be chosen to have minimal reaction or miscibility in contact with lithium in “both directions”—i.e., the Li moving into the metallic current collector to form a solid solution and vice versa. In addition, the metallic current collector may be selected for its low reactivity and diffusivity to the oxidants from the ambient. Some potential candidates for the first requirements may be Cu, Ag, Al, Au, Ca, Co, Sn, Pd, Zn and Pt. With some materials, the thermal budget may need to be managed to ensure there is no reaction/diffusion between the metallic layers. If a single metal element is incapable of meeting both requirements, then alloys may be considered. Also, if a single layer is incapable of meeting both requirements, then dual (or multiple) layers may be used. Furthermore, in addition an adhesion layer may be used in combination with a layer of one of the aforementioned refractory and non-oxidizing layers—for example, a Ti adhesion layer in combination with Au. The current collectors may be deposited by (pulsed) DC sputtering of metal targets to form the layers (e.g., metals such as Cu, Ag, Pd, Pt and Au, metal alloys, metalloids or carbon black). Furthermore, there are other options for forming the protective barriers to the shuttling lithium ions, such as dielectric layers, etc.

FIG. 3 shows, as an example, a top-down plan view schematic representation of an inline vertical deposition system 300. The system may comprise multiple modular chambers 301 with components to enable vacuum deposition of various layers—vacuum pumps 302, loadlocks 303, chambers/conduits through which substrates 310 pass in front of the multiple deposition sources 321-324 (e.g. sputter deposition sources) and laser processing tools 331-334. The deposition sources may be for different device layers or, when needed, for multiple depositions of the same material to build up the thickness of a particular device layer. Although the deposition system is shown with a vertical substrate orientation, an in-line deposition system with a horizontally orientated substrate may also be used in embodiments. Furthermore, in some embodiments non-vacuum deposition and laser processing may be used; in some embodiments there may be a mix of vacuum and non-vacuum modules within a system.

The strategic positions of the laser processing tools relative to the deposition sources for providing energy to the deposited layer for improving the quality of the deposited materials are shown in FIG. 3. There are multiple configurations for integration of laser processing. The specific number and location of the laser processing tools will depend, to name a few factors, on the layer thickness (deposition rate from a source), desired energy level to induce the effects, and speed of the carrier. There are two different modes for integration of the laser processing tools and the device layer deposition sources. The first is the true laser assisted mode, wherein the laser beam is directed onto the sputtering/deposition zone on the substrate/device stack surface (Source 3/Laser 3 in FIG. 3). The second is in-situ but post deposition thermal treatment (surface restructuring/recrystallization/densification) of the deposited layer (Sources 1, 2 and 4/Lasers 1, 2 and 4 in FIG. 3). In the second case, the laser processing tool may be positioned between two deposition sources, such that the laser beam is beyond the sputtering/depositing plasma zone.

Furthermore, the gas environment—pressure and composition—may be controlled independently within different processing modules of the in-line system with the use of gate valves/limiting apertures between the modules which have independent vacuum pumps. For example, maintaining a higher oxygen partial pressure within the laser processing module during annealing of a LiCoO₂ (LCO) device layer may provide improved material characteristics—a high partial pressure of oxygen, 15% to 100% O₂ chamber ambient, will enhance formation of the high temperature phase of LCO—a desirable crystallinity. If this method is utilized for deposition of a LiCoO₂ cathode—a relatively thick device layer of approximately up to 30 to 50 microns—multiple sequential depositions and laser anneals may be needed, and the oxygen partial pressure in the laser annealing modules will be maintained at a higher level than in the deposition modules. In the deposition of a LLZO electrolyte—a device layer of approximately up to 3 microns thickness—multiple sequential depositions and laser anneals may be needed, and the oxygen partial pressure in the laser annealing modules will be maintained at a higher level than in the deposition modules.

The lasers may be selected as follows. First, the wavelength is selected based on the optical characteristics of the depositing layer (optical absorption based on its n and k values vs. frequency) and, if selectivity is needed, a wavelength away from the surrounding materials' k-value maximum. Second, the pulse frequency and exposure time (or rastering speed) is chosen based on the desired “depth and duration” of the heat loading (to higher pulse frequency to maximize localization) and the desired dissipation/propagation. CW lasers can be considered as well. Third, the power is chosen to be sufficient to achieve the desired effects such as surface restructuring/crystalline phase/crystallinity/densification of the layer. While the specification may focus on these battery materials, the methods described herein equally apply to other material types, deposition methods and applications.

An example of laser selection for processing a LiCoO₂ material layer is a solid state Nd:YAG frequency doubled 532 nm laser, another example is a fiber laser frequency doubled to roughly 0.5 microns.

FIGS. 4 & 5 provide examples of process flows for the deposition of an electrochemical device layer, according to embodiments. A shown in FIG. 4, a process for fabricating an electrochemical device may comprise: providing an electrochemical device substrate/device stack (401); depositing a device layer over the substrate/device stack (402); after the depositing, laser processing the device layer to effect surface restructuring/recrystallization/densification of the device layer (403); repeating the depositing and laser processing until a desired device layer thickness is achieved (404). The electrochemical device may be a TFB, an electrochromic device, or other device. The device layer may be a layer of LiCoO₂ material, LLZO material, or other electrochemical device material. If this method is utilized for deposition of a LiCoO₂ cathode—a relatively thick device layer of roughly up to 30 to 50 microns—multiple sequential depositions and laser anneals may be needed.

As shown in FIG. 5, a process for fabricating an electrochemical device may comprise: providing an electrochemical device substrate/device stack (501); depositing a device layer over the substrate/device stack and during the depositing, laser processing the device layer to facilitate surface restructuring/crystallization/densification of the device layer (502); repeating the depositing and laser processing until a desired device layer thickness is achieved (503). The electrochemical device may be a TFB, an electrochromic device, or other device. The device layer may be a layer of LiCoO₂ material, LLZO material, or other electrochemical device material.

In embodiments, the device layer may be exposed to pulses of electromagnetic radiation as described as follows. A plurality of treatment zones is generally defined on the substrate and exposed to the pulses sequentially. In one embodiment, the pulses may be pulses of laser light, each pulse having a wavelength between about 200 nm and about 1200 nm, for example about 532 nm as delivered by a frequency-doubled Nd:YAG laser. In embodiments, a CO₂ laser may be used to deliver energy. Other wavelengths, such as infrared, ultraviolet, and other visible wavelengths, may also be used. The pulses may be delivered by one or more sources of electromagnetic radiation, and may be delivered through an optical or electromagnetic assembly to shape or otherwise modify selected characteristics of the pulses.

The device layer may be progressively heated to a temperature to permit surface restructuring/recrystallization/densification by treatment with the pulses of laser light. Each pulse of laser light may have energy enough to heat the portion of the device stack on which it impinges to activate the surface restructuring/recrystallization/densification of the device layer, For example, for 30 ns laser pulses each pulse may deliver energy between about 0.1 J/cm² and about 1.0 J/cm², and more generally, the fluence needs to be adjusted within the range of several mJ/cm² to several J/cm² depending on the pulse duration. A single pulse impacts the substrate surface, transferring much of its energy into the substrate material as heat. The first pulse impacting the surface impacts a solid material, heating it to the activation temperature. Depending on the energy delivered by the first pulse, the surface region may be heated to a depth of between about 6 nm and about 60 nm. The next pulse to reach the surface impacts the activated material, delivering heat energy that propagates through the activated material into the surrounding material, activating more of the device layer. In this way, successive pulses of electromagnetic radiation may form a front of activated material that moves through the device layer with each successive pulse. The activated portion of the device layer undergoes surface restructuring/recrystallization/densification to form a device layer with improved material characteristics.

Furthermore, in embodiments the interval between pulses may be long enough to allow the energy imparted by each pulse to dissipate completely. Thus, each pulse completes a micro-anneal cycle. The pulses may be delivered to the entire substrate at once or to portions of the substrate at a time.

Furthermore, in embodiments the thermal budget for the annealing of a device layer may be managed to reduce thermally induced stresses within the device layer and between adjacent device layers in the device stack. For example, first laser pulses to a particular area of the wafer may preheat the wafer to a temperature between the ambient and the anneal temperature forming a preheated region, then second laser pulses may increase the temperature of a portion of the preheated region to the annealing temperature, wherein the portion being annealed is surrounded by preheated material in order to reduce the thermal stress. Using this approach an annealing front may be moved across the device layer, always having a preheated region ahead of the annealing front to reduce thermal stress in the device layer being annealed, and always having a preheated region below the portion being annealed to reduce the thermal stress between adjacent layers in the device stack. Furthermore, thermal budget management may be used to minimize the amount of heat deposited into the stack of device layers when annealing the top layer of the stack, thus reducing the temperature experienced by underlying layers in the stack. The latter is important, for example, to enable annealing of a crystalline anode layer over a LiPON electrolyte without altering the amorphous state of the LiPON electrolyte—an example of such a crystalline anode material is a Li salt material such as Li₄Ti₅O₁₂ that has a lower chemical potential vs. Li than the cathode materials.

The laser assisted deposition proposed herein can enable the deposition of an LLZO electrolyte layer by creating the desired crystalline phase without, or minimizing, the detrimental effect of post-deposition annealing to form this electrolyte material. First, LLZO in crystalline phase (as opposed to microcrystalline or amorphous) has the highest ionic conductivity—ionic conductivity of cubic LLZO is of the order of 10E-4 S/cm. If high temperature, post-deposition annealing is necessary to achieve such a crystalline phase, then it is expected that the layer will react with the cathode at the electrolyte/cathode interface, forming an interlayer that will negatively impact Li ion intercalation reactions necessary for battery operation (electrochemical reactions between Li ion and an electron at the positive electrode-electrolyte interface). The reaction byproduct between LLZO and the cathode material, depending on the sintering temperature and specific cathode materials, etc., will be either electrochemically inactive (blocking) or in embodiments have an ionic conductivity that is a few times (or more) less than the ionic conductivity of the LLZO electrolyte layer, and in embodiments have an ionic conductivity that is an order of magnitude (or more) lower than the ionic conductivity of the LLZO electrolyte layer. (The reacted interlayer, between cathode and LLZO, would in embodiments have an ionic conductivity less than that of UPON or the amorphous phase of LLZO—typically less than or equal to 10E-7 S/cm.) In addition, it is expected that the post deposition annealing will lead to thermal stress (heating and cooling cycles of the annealing process leading to stress induced cracks in the layer and thereby presenting a shorting path when the subsequent Li anode is deposited). As such, if the LLZO layer can be formed with desirable crystallinity during deposition either without or with very minimal thermal treatment after the deposition, then such detrimental situations can be avoided. It is expected that a laser heating process, using a laser with appropriate wavelength and pulse duration selection, as described herein, can limit the heating to the necessary layer (LLZO) to effect the desirable crystallization and phase formation reaction without affecting the interface and/or the substrate for minimal interfacial reactions and stress formation. At the same time, this method affords a simple improved densification route with the thinner, growing layers and avoids the need for annealing the full stack thickness. As such, the in situ laser assisted deposition can overcome the limitation of conventional layer fabrication and formation methodologies.

For example, according to embodiments a thin film battery may comprise: a substrate; a current collector on the substrate; a cathode layer on the current collector; an electrolyte layer on the cathode layer; and a lithium anode layer on the electrolyte layer; wherein the LLZO electrolyte layer has a crystalline phase, no shorts due to cracks in the LLZO electrolyte layer, and no highly resistive interlayer at the interface between the electrolyte layer and the cathode layer.

The logic for LCO layer formation is analogous to that for LLZO. It is expected that the in situ densification and phase formation for LCO, with minimal internal stress and surface/bulk cracking, will lead to improved device performance and yield. It is expected that dense LCO films with minimal stress will lead to better capacity utilization numbers versus the theoretical limitation of LCO. The lower stress and better surface morphology will lead to better device yield and stability during subsequent electrolyte deposition and over the operation of the battery as it undergoes volume expansion and contraction with cycling.

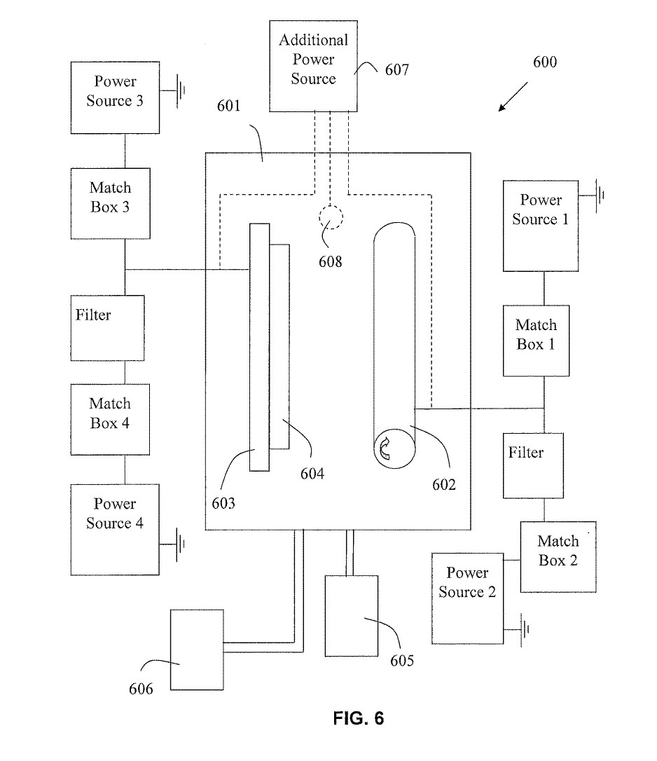

Returning to FIG. 3, an example of a deposition tool that can be used in the in-line deposition system is a plasma-assisted sputter deposition system such as shown in FIG. 6. FIG, 6 shows a schematic representation of an example of a deposition tool 600 configured for deposition methods according to present embodiments. The deposition tool 600 includes a vacuum chamber 601, a sputter target 602 and a substrate carrier 603 for holding and moving a substrate 604 through the sputter deposition tool 600 during sputter deposition. The chamber 601 has a vacuum pump system 605 for controlling the pressure in the chamber and a process gas delivery system 606. Furthermore, FIG. 6 shows an additional power source 607, which may be connected to either substrate or target, connected between target and substrate, or coupled directly to the plasma in the chamber using an electrode 608. An example of the latter is the power source 607 being a microwave power source coupled directly to the plasma using an antennae (electrode 608); although, microwave energy may be provided to the plasma in many other ways, such as at a remote plasma source. A microwave source for coupling directly with the plasma may include an electron cyclotron resonance (ECR) source.

Multiple power sources may be connected to the sputter target in FIG. 6. Each target power source has a matching network for handling radio frequency (RF) power supplies. A filter is used to enable use of two power sources connected to the same target/substrate to operate at different frequencies, where the filter acts to protect the target/substrate power supply operating at the lower frequency from damage due to the higher frequency power. Similarly, multiple power sources may be connected to the substrate. Each power source connected to the substrate has a matching network for handling radio frequency (RF) power supplies. Furthermore, a blocking capacitor may be connected to the substrate carrier 603 in order to induce a different carrier/chamber impedance to modulate the self-bias of surfaces within the process chamber, including the target and substrate, and thereby induce different: (1) sputtering yields on the target and (2) kinetic energy of adatoms, for modulation of growth kinetics. The capacitance of the blocking capacitor may be adjusted in order to change the self-bias at the different surfaces within the process chamber, importantly the substrate surface and the target surface.

Although FIG. 6 shows a chamber configuration with horizontal planar target and substrate, the target and substrate may be held in vertical planes for integration into a vertical in-line system such as shown in FIG. 3. The target 602 may be a rotating or oscillating cylindrical target as shown, dual rotatable cylindrical targets may also be used, or the target may have some other non-planar or planar configuration. Here the term oscillating is used to refer to limited rotational motion in any one direction such that a solid electrical connection to the target suitable for transmitting RF power can be accommodated. Furthermore, the match boxes and filters may be combined into a single unit for each power source. One or more of these variations may be utilized in deposition tools according to some embodiments.

According to some embodiments, different combinations of power sources in the deposition system of FIG. 6 may be used by coupling appropriate power sources to the substrate, target and/or plasma. Depending on the type of plasma deposition technique used, the substrate and target power sources may be chosen from DC sources, pulsed DC (pDC) sources, AC sources (with frequencies below RF, typically below 1 MHz), RF sources, etc, in any combinations thereof. The additional power source may be chosen from pDC, AC, RF, microwave, a remote plasma source, etc. RF power may be supplied in continuous wave (CW) or burst mode. Furthermore, the target may be configured as an HPPM (high-power pulsed magnetron). For example, combinations may include dual RF sources at the target, pDC and RF at the target, etc. (Dual RF at the target may be well suited for insulating dielectric target materials, whereas pDC and RF or DC and RF at the target may be used for conductive target materials. Furthermore, the substrate bias power source type may be chosen based on what the substrate pedestal can tolerate as well as the desired effect.)

As discussed above, the deposition and laser processing hardware and the processing methods are expected to be agnostic to the method of material deposition. As such, the deposition hardware and method described with reference to FIG. 6 is only one of many deposition options.

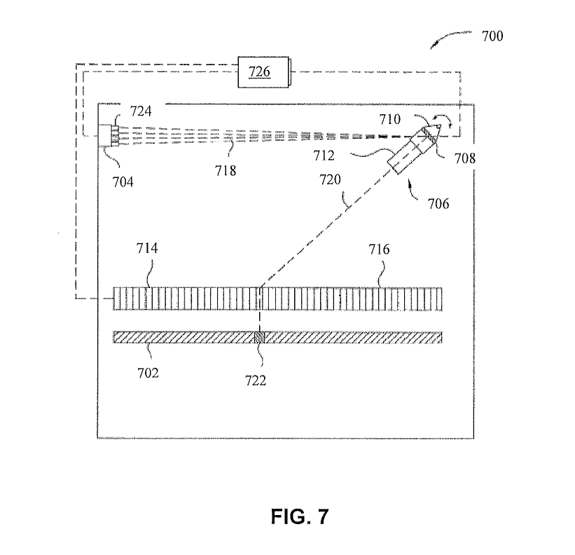

Returning to FIG. 3, examples of laser processing tools that can be used in the in-line deposition system for in situ thermal processing of electrochemical device layers are shown in FIGS. 7-9. In general, the laser processing tools may have one or more of the following features: one or more lasers, such as Nd:YAG, CO₂ and fiber lasers; laser spot size and shape variation; laser beam movement over the surface of the electrochemical device using, for example, rotating polygons, galvanometer scanner, etc.; pulse train capability; and thermal budget management capability.

FIG. 7 is a schematic cross-sectional view of an apparatus 700 according to some embodiments. The apparatus generally comprises a chamber 701 with a substrate carrier 702 movable therethrough. A source of electromagnetic energy 704 is disposed in the chamber, or in another embodiment may be disposed outside the chamber and may deliver the electromagnetic energy to the chamber through a window in the chamber wall. The source of electromagnetic energy 704 directs one or more beams of electromagnetic energy 718, such as laser beams, from one or more emitters 724 toward an optical assembly 706. The optical assembly 706, which may be an electromagnetic assembly, forms the one or more beams of electromagnetic energy into a train 720 of electromagnetic energy, directing the train 720 of energy toward a rectifier 714. The rectifier 714 directs the train 720 of energy toward a treatment zone 722 of the substrate support 702, or of a substrate disposed thereon.

The optical assembly 706 may comprise a moveable reflector 708, which may be a mirror, and an optical column 712 aligned with the reflector 708. The reflector 708 is mounted on a positioner 710 which, in the embodiment of FIG. 7, rotates to direct a reflected beam toward a selected location. In other embodiments, the reflector may translate rather than rotating, or may both translate and rotate. The optical column 712 forms and shapes pulses of energy from the energy sources 704, reflected by the reflector 708, into a desired energy train 720 for treating a substrate on the substrate carrier 702.

The rectifier 714 may comprise a plurality of optical cells 716 for directing the energy train 720 toward the treatment zone 722. The energy train 720 is incident on one portion of an optical cell 716, which changes the direction of propagation of the energy train 720 to a direction substantially perpendicular to the substrate support 702 and the treatment zone 722. Provided a substrate disposed on the substrate carrier 702 is flat, the energy train 720 leaves the rectifier 714 travelling in a direction substantially perpendicular to the substrate, as well.

The optical cells 716 may be lenses, prisms, reflectors, or other means for changing the direction of propagating radiation. Successive treatment zones 722 are treated by pulses of electromagnetic energy from the energy source 704 by moving the optical assembly 706 such that the reflector 708 directs the energy train 720 to successive optical cells 716.

In one embodiment, the rectifier 714 may be a two-dimensional array of optical cells 716 extending over the substrate carrier 702. In such an embodiment, the optical assembly 706 may be actuated to direct the energy train 720 to any treatment zone 722 of the substrate carrier 702 by reflecting the energy train 720 toward the optical cell 716 above the desired location. In another embodiment, the rectifier 714 may be a line of optical cells 716 with length greater than or equal to a dimension of the substrate carrier. A line of optical cells 716 may be positioned over a portion of a substrate, and the energy train 720 scanned across the optical cells 716 to treat portions of the substrate located below the rectifier 714, multiple times if desired, and then the line of optical cells 716 may be moved to cover an adjacent row of treatment zones, progressively treating an entire substrate by rows.

The energy source 704 of FIG. 7 shows four individual beam generators because in some embodiments, individual pulses in a pulse train may overlap. Multiple beam or pulse generators may be used to generate pulses that overlap. Pulses from a single pulse generator may also be made to overlap by use of appropriate optics in some embodiments. Use of one or more pulse generators will depend on the exact characteristics of the energy train needed for a given embodiment.

The interdependent function of the energy source 704, the optical assembly 706 and the rectifier 714 may be governed by a controller 726. The controller may be coupled to the energy source 704 as a whole, or to individual energy generators of the energy source 704, and may control power delivery to the energy source, or energy output from the energy generators, or both. The controller 726 may also be coupled to an actuator (not shown) for moving the optical assembly 706, and an actuator (not shown) for moving the rectifier 714, if necessary. Furthermore, the substrate carrier 702 may be moved in or out of the plane of the figure along the process line during laser heat treatment, and furthermore, in some embodiments there is no rectifier in the laser processing tool.

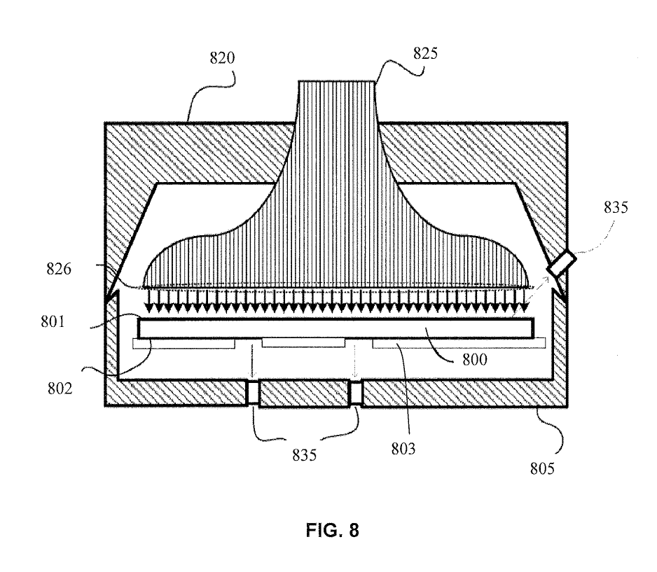

The second example of a laser processing tool that can be used in the in-line deposition system for in situ thermal processing of electrochemical device layers is shown in FIG. 8. FIG. 8 is a cross-sectional schematic of a laser processing tool according to some embodiments. FIG. 8 shows a laser processing tool into which light is passed through fiber optic cabling 825 into the chamber and spread across a substrate 800 on a substrate carrier 803 to process the surface without relative motion between the output of the fiber laser assembly 826 and the substrate 800, although movement of the substrate carrier in or out of the plane of the figure along the process line may be utilized during the laser processing. Furthermore, motion of the substrate carrier relative to the fiber optic cabling may be provided if needed by a combination of a motion of the substrate and a motion of the output of the fiber laser assembly.

For pulses below about 20 milliseconds in duration, the substrate may not be the same temperature at the top surface 801 and bottom surface 802 until after the pulse is terminated. Optical measurements of the thermal response to illumination may therefore be preferably performed on the top surface 801 which is directly illuminated and heated. Monitoring the top surface 801 may be done through a transparent optical aperture 835 aimed at the surface of substrate 800 (through apertures in the substrate carrier 803) rather than through the transparent optical apertures 835 aimed at the bottom surface 802. The processing system shown is configured with the transparent optical aperture 835 as part of the lid 820 which also supports the fiber optic cabling 825. The thermal response of the top surface 801 of substrate 800 may be monitored by pyrometry at a wavelength different from the wavelength(s) of light emitted from the fiber laser(s) to improve the accuracy of a temperature determination. Detecting a different wavelength can reduce the chance that illumination reflected or scattered from the fiber laser will be misinterpreted as being thermally generated from the top surface of substrate 800.

Since pulses from the fiber laser may be as short as 2 nanoseconds, the light detected by a pyrometer may not be indicative of an equilibrium temperature of the surface. Further processing may be required in order to determine the actual temperature of the surface during or after the laser exposure. Alternatively, the raw optical signal may be used and correlated to optimum properties of the resulting film, dopant or other surface characteristics. In FIG. 8 the fiber laser assembly 826 outputs light inside the processing chamber. In an alternative embodiment, the fiber laser output 826 may be located outside the processing chamber and light is passed into the chamber through a transparent window. In another alternative embodiment, the fiber laser output 826 may occupy a separate portion of the chamber where it is still protected from process conditions. Separating the output of the fiber laser 826 from the processing region has the additional advantage of preventing deposition, etching or other reactions which adversely affect the efficiency of transmission of optical radiation through to the surface of substrate 800.

The fiber laser may produce light of short wavelength (<0.75 μm or <0.5 μm in embodiments) while making pyrometry measurements at a longer wavelength (between about 0.5 μm and 1.2 μm or 0.75 μm and 1.2 μm) in order to separate heating wavelengths from monitoring wavelengths. The fiber optic cabling 825 shown in FIG. 8 may or may not be a portion of the doped laser cavity, but may be an undoped fiber used to transmit the light into the chamber from the laser cavity.

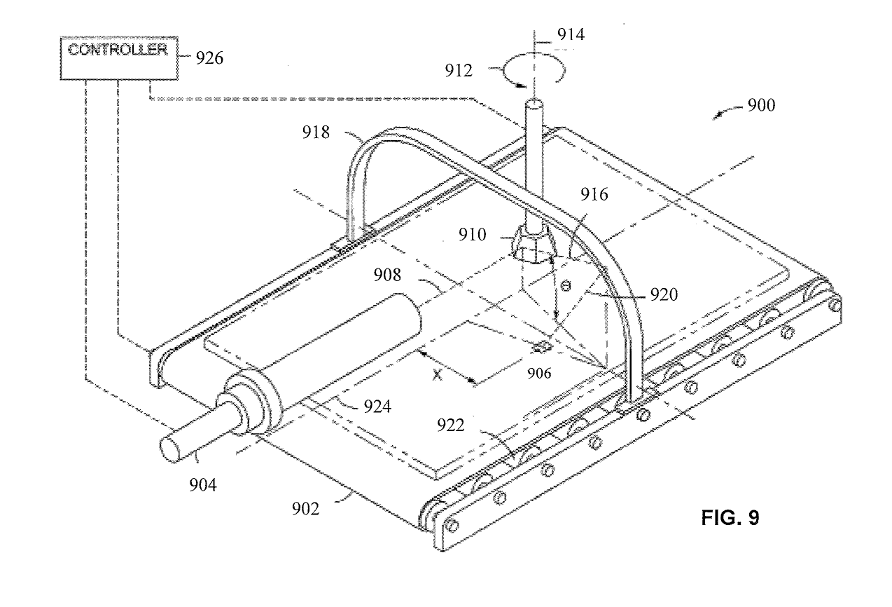

The third example of a laser processing tool that can be used in the in-line deposition system for in situ thermal processing of electrochemical device layers is shown in FIG. 9. FIG. 9 is a perspective view of a thermal processing apparatus 900 according to another embodiment. A work surface 902, which may be movable as indicated schematically by rollers 922, provides a work space for positioning a substrate. A laser 904 produces a directed energy stream 908 of radiant energy along a path substantially parallel to the plane defined by the work surface 902, and toward an energy distributor 910. The energy distributor 910 may be a reflector or a refractor, and rotates as indicated by arrow 912 to deflect the directed energy stream 908 toward a collector 918, which is an optical element, or collection thereof, that collects the energy of the directed energy stream 908 and directs the collected energy towards the substrate. The energy distributor 910 generally has a motor that rotates the energy distributor at a desired rate. The energy distributor 910 is supported at a desired location above the work surface 902 by a support 914.

The energy distributor 910 sends a reflected stream 916 of directed energy toward the collector 918, which sends the reflected stream 916 toward the work surface 902 in a normal stream 920, which is a stream of directed energy normal to the work surface 902. The collector 918 has a reflective surface that faces the work surface 902. The reflective surface has a shape that reflects the directed energy such that a distance “x” of the exposed area 906 of the work surface 902 from a center line 924 of the work surface 902 is substantially proportional to an angular elevation 6 of the reflected energy stream 916 above the plane defined by the work surface 902. The collector 918 may have a plurality of flat mirrors, a continuous faceted mirrored surface, or a continuous curved mirror surface.

A substrate may be continuously translated through the apparatus 900 under the collector 918 while pulses of energy are directed to the substrate by way of the rotating energy distributor 910. The substrate may also be translated stepwise through the apparatus. Optics may also be included, if desired, to confine divergent light as it approaches the energy distributor, and the energy distributor may have focusing optics, such as curved reflective or refractive surfaces, to compensate for differential divergence or loss of coherence due to different path length, if desired. A controller 926 controls the rotation of the energy distributor 910, the pulse rate of the laser 904 and the translation of the substrate to achieve a desired treatment program. The rotation of the energy distributor 910, the pulse rate of the energy source 904, and the translation of the substrate may be synchronized by the controller 926 to match an edge of one treatment zone 906 of the substrate to an edge of an adjacent treatment zone to achieve uniform treatment of the substrate by piecing together rectangular treatment zones, particularly if the rectangular energy field applied to each treatment zone is uniform.

In alternate embodiments, a high repetition rate radiation source may be coupled with two movable mirrors to position a radiation field for processing different target zones of a substrate. The movable mirrors may be scanned through a pattern as the radiation source is pulsed such that the target zones are processed according to any desired pattern, with the rate of movement of the mirrors related to the repetition rate of the radiation source.

A method according to an embodiment may be used in thermal processing of electrochemical device layers using a tool as shown in FIG. 9. First, treatment zones are defined on an electrochemical device layer to be processed. The treatment zones are typically defined in accordance with the size and shape of an energy field to be applied to each treatment zone. The position of each treatment zone is likewise defined to provide substantially precise alignment of the treatment zone boundaries, overlap of portions of the treatment zones, or space between the treatment zones, as desired. As described above in connection with FIG. 9, rectangular treatment zones may be aligned by synchronizing pulse rate, rotation rate of the polygonal mirror, and translation rate of the substrate.

Second, the substrate with the electrochemical device layer is positioned on a work surface such that a subset of the treatment zones is exposed to an energy apparatus. The energy apparatus delivers energy to a work surface, on which the substrate rests, by way of an energy distributor. Positioning the substrate may be accomplished by moving a work stage on which the substrate rests or by directly manipulating the substrate using a carrier or a rolling tray.

Third, a plurality of energy pulses are delivered to the energy distributor proximate the substrate. The energy pulses are laser pulses. For example, laser pulses of 20 ns to 50 ns in duration can be delivered with cross-sectional energy density averaging about 0.5 J/cm², with a standard deviation of about 3% or less. The energy pulses may be delivered with constant intervals between the pulses, or with longer intervals defining pulse groups with shorter intervals.

Fourth, the energy distributor that receives the plurality of energy pulses is rotated at a constant rate to deliver an energy pulse to each treatment zone of the subset. The energy distributor changes the direction the energy pulses propagate as it rotates, receiving the energy pulses along a constant optical path and redirecting them to an optical path that changes with rotation of the energy distributor. The energy distributor may be reflective or refractive, for example mirrors, prisms, lenses, and the like. The energy distributor may include optical elements that compensate for non-linearity in projecting the rotational aspect of the energy distributor onto the planar surface of the substrate, if a planar substrate is used.

The laser processing tools and methods described above with reference to FIGS. 7-9 are only three examples of many laser processing tools and methods that may be used in the systems and process methods of the present disclosure.

Although embodiments of the present disclosure have been particularly described with reference to in-line systems with deposition and integrated laser processing and process methods on in-line systems for fabrication of electrochemical devices, further embodiments include cluster tools with deposition and integrated laser processing and process methods on cluster tools.

Although embodiments of the present disclosure have been described herein with reference to processes and tools including laser processing for fabricating TFBs, the teaching and principles of the present disclosure are expected to also be applicable to the processing of other electrochemical devices such as electrochromic devices.

Although embodiments of the present disclosure have been particularly described with reference to certain embodiments thereof, it should be readily apparent to those of ordinary skill in the art that changes and modifications in the form and details may be made without departing from the spirit and scope of the disclosure.

What is claimed is:

1. A method of fabricating an electrochemical device in an apparatus, comprising:
providing an electrochemical device substrate;
depositing a device layer over said substrate;
applying electromagnetic radiation to said device layer in situ to effect one or more of surface restructuring, recrystallization and densification of said device layer;
repeating said depositing and said applying until a desired device layer thickness is achieved.

2. The method as in claim 1, wherein said applying is after said depositing.

3. The method as in claim 1, wherein said applying is during said depositing.

4. The method as in claim 1, wherein said electrochemical device substrate comprises a stack of device layers on the surface of said electrochemical device substrate.

5. The method as in claim 1, wherein said electrochemical device is a thin film battery.

6. The method as in claim 1, wherein said applying electromagnetic radiation is laser processing.

7. The method as in claim 1, wherein said device layer is a layer of LiCoO₂ material.

8. The method as in claim 1, wherein said device layer is a layer of LLZO material.

9. The method as in claim 1, wherein said applying comprises laser pulse train annealing.

10. The method as in claim 1, wherein said applying comprises thermal budget management.

11. An apparatus for manufacturing electrochemical devices, comprising:
a first system for depositing a device layer over said substrate;
a second system for applying electromagnetic radiation to said device layer to effect one or more of surface restructuring, recrystallization and densification of said device layer;
a third system for repeating said depositing and a fourth system for repeating said applying.

12. The apparatus as in claim 11, wherein said apparatus is an in-line apparatus.

13. The apparatus as in claim 11, wherein said second system comprises a laser and said fourth system comprises a laser.

14. The apparatus of claim 11, wherein said applying is during said depositing,

15. A thin film battery comprising:
a substrate;
a current collector on said substrate;
a cathode layer on said current collector;
an electrolyte layer on said cathode layer; and
a lithium anode layer on said electrolyte layer;
wherein said LLZO electrolyte layer has a crystalline phase, no shorts due to cracks in said LLZO electrolyte layer, and no highly resistive interlayer at the interface between said electrolyte layer and said cathode layer.
